(19) United States
(12) Patent Application Publication
(10) Pub. No.: US 2006/0250162 A1
(43) Pub. Date: Nov. 9, 2006

(54) SIGNAL AMPLIFICATION CIRCUIT FOR HIGH-SPEED OPERATION AND SEMICONDUCTOR MEMORY DEVICE HAVING THE SAME

(75) Inventors: Du-Yeul Kim, Gyeonggi-do, (KR); Jun-Hyung Kim, Gyeonggi-do, (KR); Tai-Young Ko, Seoul (KR); Sang-Bo Lee, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Suwon-si (KR)

(21) Appl. No.: 11/379,200

(22) Filed: Apr. 18, 2006

(30) Foreign Application Priority Data
Apr. 18, 2005 (KR) 2005-31762
Jun. 21, 2005 (KR) 2005-53460
Aug. 4, 2005 (KR) 2005-71218

(51) Int. Cl. H03F 3/45

(52) U.S. Cl. 327/55

(57) ABSTRACT

A signal amplification circuit for a semiconductor memory device includes a current sense amplifier configured to receive a first signal pair and generate a second signal pair on a first pair of lines, an equalizer configured to equalize the first pair of lines, and a latch amplifier configured to generate a latch data output on a second pair of lines in response to the second signal pair.

### BACKGROUND OF THE INVENTION

This application claims priority under 35 U.S.C. § 119 to Korean Patent Application Nos. 2005-31762, 2005-53460 and 2005-71218, filed on Apr. 18, 2005, Jun. 21, 2005 and Aug. 4, 2005, respectively, the contents of which are herein incorporated by reference in their entirety for all purposes.

1. Field of the Invention

This disclosure relates generally to a signal amplification circuit for producing an output signal by detecting and amplifying a received signal pair and a semiconductor memory device including the signal amplification circuit.

2. Description of the Related Art

In general, a signal amplification circuit amplifies a small voltage difference of a signal pair on a transmission line and provides an output signal corresponding to the voltage difference. The signal amplification circuit of a semiconductor memory device detects and amplifies the current difference of a received data signal pair while reading data stored in a memory cell in charge form through a transmission line.

FIG. 1 is a block diagram schematically illustrating a semiconductor memory device including conventional signal amplification circuit 10. The signal amplification circuit 10 of FIG. 1 includes a current sense amplifier 11, a latch amplifier 15 and an output switch 19. The current sense amplifier 11 detects and amplifies the current difference of a data signal pair DIN and /DIN that is provided from a memory block 20, a bit line sense amplifier 30 and a transmission switch 40. The latch amplifier 15 latches data based on the detected and amplified signal pair CSA and /CSA provided from the current sense amplifier 11. The output switch 19 provides the output signal LOUT of the latch amplifier 15 in response to an output control signal FRP. The control circuit 50 produces signals that control the transmission switch 40 and the signal amplification circuit 10, in response to an external control signal ECON. In this case, the current sense amplifier 11 is generally set to very high amplification gain so as to sufficiently develop the detected and amplified signal pair CSA and /CSA in a short time.

Meanwhile, in a conventional signal amplification circuit, the detected and amplified signal pair CSA and /CSA provided from the current sense amplifier 11 has a delay time with respect to a data signal pair DIN and /DIN, as shown in FIG. 2. That is, a considerable delay time tL occurs between the reception of a second data signal DIN2 and a third data signal DIN3 and the development of the respective detected and amplified signal pair CSA and /CSA. As a result, the conventional signal amplification circuit 10 is problematic in that invalid data may be generated during high-speed operations.

### SUMMARY OF THE INVENTION

An embodiment includes a signal amplification circuit for a semiconductor memory device including a current sense amplifier configured to receive a first signal pair and generate a second signal pair on a first pair of lines, an equalizer configured to equalize the first pair of lines, and a latch amplifier configured to generate a latch data output on a second pair of lines in response to the second signal pair.

Another embodiment includes a signal amplification circuit for a semiconductor memory device including a differential amplifier configured to receive a first signal pair on a first pair of lines and to generate a second signal pair on a second pair of lines, an equalizer configured to equalize the second pair of lines, and a latch amplifier configured to generate a latch data output on a third pair of lines in response to the second signal pair.

### BRIEF DESCRIPTION OF THE DRAWINGS

The above and other objects, features and advantages of embodiments of the invention will be more clearly understood from the following detailed description taken in conjunction with the accompanying drawings, in which:

FIG. 1 is a block diagram schematically illustrating a semiconductor memory device including a conventional signal amplification circuit;

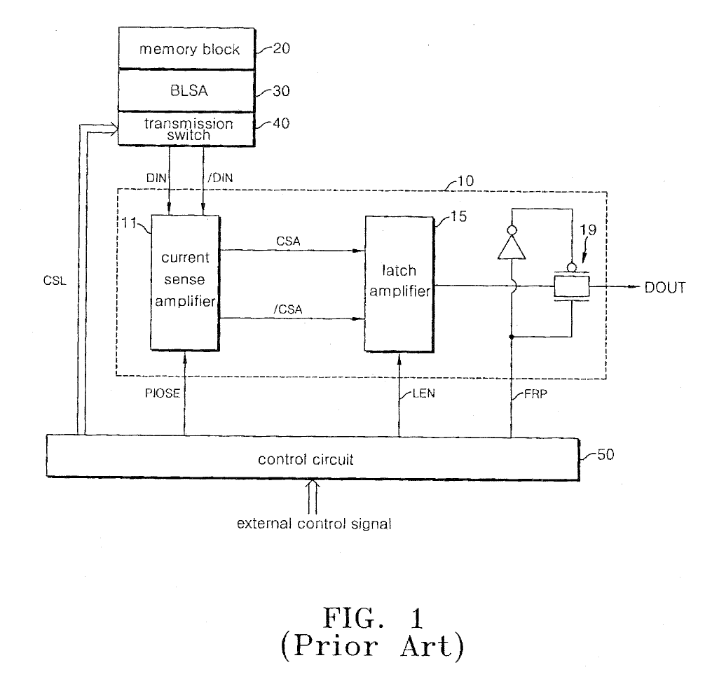

FIG. 2 is a timing diagram illustrating the occurrence of a time delay in the conventional signal amplification circuit;

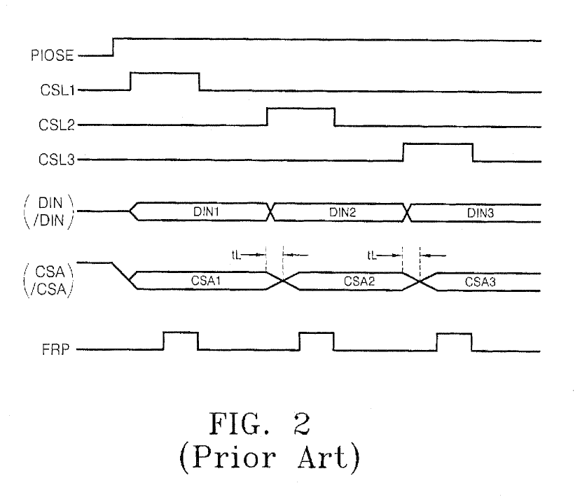

FIG. 3 is a block diagram schematically illustrating a semiconductor memory device including a signal amplification circuit according to an embodiment;

FIG. 4 is a circuit diagram illustrating the current sense amplifier of FIG. 3 in detail;

FIG. 5 is a circuit diagram illustrating the latch amplifier of FIG. 3 in detail;

FIG. 6 is a timing diagram illustrating the operation of the signal amplification circuit according to the embodiment of FIG. 3;

FIG. 7 is a block diagram schematically illustrating a semiconductor memory device including a signal amplification circuit according to another embodiment;

FIG. 8 is a circuit diagram illustrating the differential amplifier 230 of FIG. 7 in detail;

FIG. 9 is a block diagram schematically illustrating a semiconductor memory device including a signal amplification circuit according to another embodiment;

FIG. 10 is a timing diagram illustrating the operation of the signal amplification circuit according to the embodiment of FIG. 9;

FIG. 11 is a block diagram schematically illustrating a semiconductor memory device including a signal amplification circuit according to still another embodiment; and

FIG. 12 is a timing diagram illustrating the operation of the signal amplification circuit according to the embodiment of FIG. 11.

### DETAILED DESCRIPTION

Reference now should be made to the drawings, in which the same reference numerals are used throughout the different drawings to designate the same or similar components. Embodiments will be described in detail below with reference to the accompanying drawings.

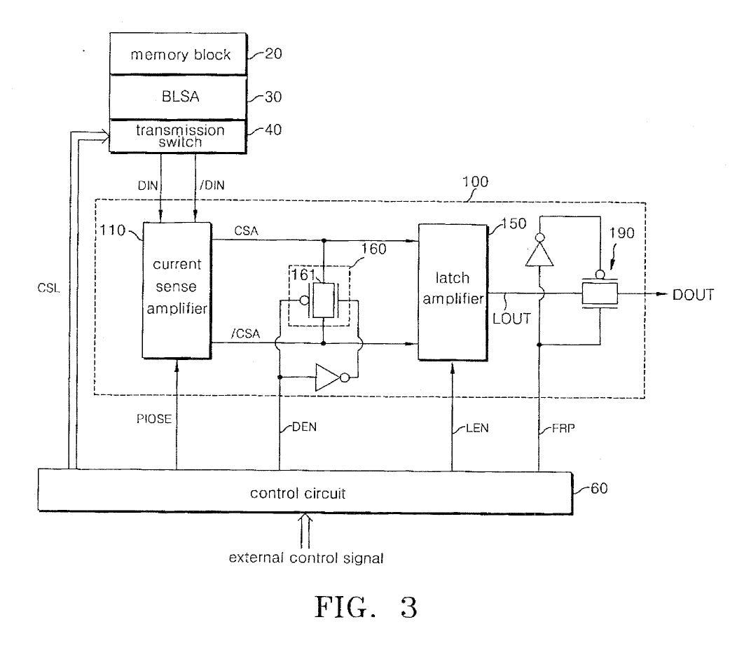

FIG. 3 is a block diagram schematically illustrating a semiconductor memory device including a signal amplification circuit 100 according to an embodiment. In the semiconductor memory device of FIG. 3, a memory block 20, a bit line sense amplifier 30, a transmission switch 40, the signal amplification circuit 100 and a control circuit 60 are included.

The memory block 20 includes memory cells (not shown) that store data. The bit line sense amplifier 30 amplifies data that is transmitted during data input/output and refresh operations. The transmission switch 40 provides a data signal pair DIN and /DIN based on data stored in the memory lock 20 to the signal amplification circuit 100 in response to a column select signal CSL provided from the control circuit 60. The data signal pair DIN and /DIN may be repeatedly provided in response to column select signals CSL.

The signal amplification circuit 100 produces an output signal DOUT by detecting and amplifying the current difference of the received data signal pair DIN and /DIN. In FIG. 3, the control circuit 60 provides the column select signals CSL in response to an external control signal ECON. The control circuit 60 produces a sense enable signal PIOSE, a control enable signal DEN and a latch enable signal LEN, and provides the signals to the signal amplification circuit 100.

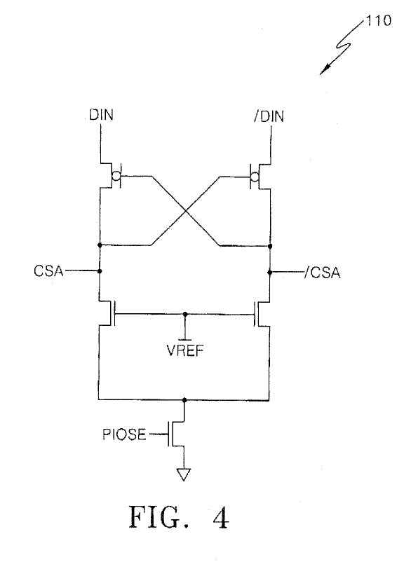

The signal amplification circuit 100 includes a current sense amplifier 110, a latch amplifier 150 and an equalizer 190. An example of the current sense amplifier 110 is illustrated in FIG. 4. Referring to FIG. 4, the current sense amplifier 110 is enabled in an interval where the sense enable signal PIOSE is “H.” The current sense amplifier 110 develops the detected and amplified signal pair CSA and /CSA by detecting and amplifying the current difference of the data signal pair DIN and /DIN. As described above, the data signal pair DIN and /DIN may be repeatedly provided from the memory block 20 in response to column select signals CSL.

Referring to FIG. 3 again, the latch amplifier 150 amplifies and latches the data of the detected and amplified signal pair CSA and /CSA provided from the current sense amplifier 110. The output switch 190 provides the output signal LOUT of the latch amplifier 150 in response to the output control signal FRP.

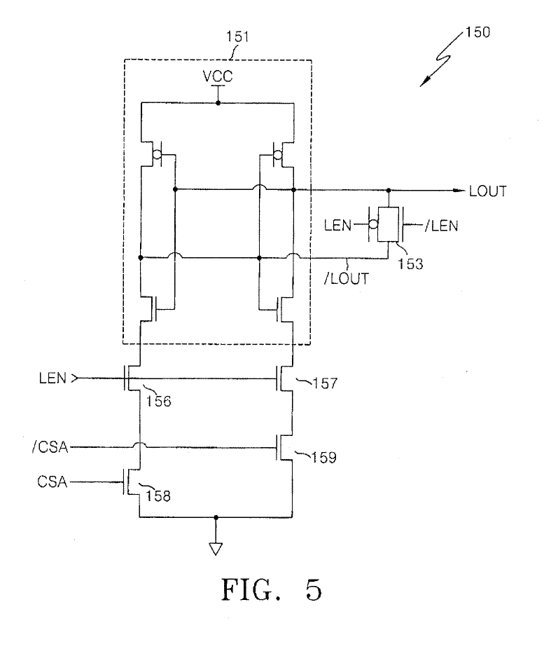

An example of the latch amplifier 150 is illustrated in FIG. 5. Referring to FIG. 5, the latch amplifier 150 includes NMOS transistors 156 and 157 for receiving a latch enable signal LEN, NMOS transistors 158 and 159 for receiving the detected and amplified signal pair CSA and /CSA, a latch 151, and a transmission gate 153 for controlling the latch. The latch amplifier 150 latches and amplifies the data of the detected and amplified signal pair CSA and /CSA in an interval where the latch enable signal LEN is “H.” Furthermore, in an interval where the latch enable signal LEN is “L,” the latch amplifier 150 equalizes the lines carrying the latch data LOUT with complementary latch data /LOUT.

Referring to FIG. 3 again, the output switch 190 is gated by the output control signal FRP, and allows the latch data LOUT to be output as output data DOUT.

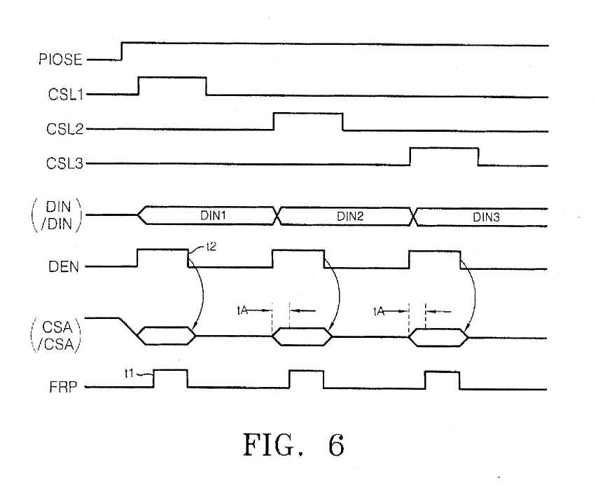

The equalizer 160 operates to equalize the lines carrying the detected and amplified signal pair CSA and /CSA. That is, after the data of the detected and amplified signal pair CSA and /CSA has been latched by the latch amplifier 190 (t1; refer to FIG. 6), the equalization of the detected and amplified signal pair CSA and /CSA is performed (t2; refer to FIG. 6). Preferably, the equalizer 160 includes a switching means 161 that electrically connects the detected and amplified signal pair CSA and /CSA when the control enable signal DEN is “L.”

Preferably, the switching means 161 is implemented using a transmission gate that is gated in response to the control enable signal DEN. The transmission gate of the switching means 161 is turned on in an interval where the control enable signal DEN is “L,” and equalizes the lines carrying the detected and amplified signal pair CSA and /CSA. In contrast, in an interval where the control enable signal DEN is “H,” the transmission gate of the switching means 161 is turned off, so that the current sense amplifier 110 can develop the detected and amplified signal pair CSA and /CSA.

As a result, after the current sense amplifier 110 has output the detected and amplified signal pair CSA and /CSA and before the current sense amplifier 110 senses and outputs subsequent data, the equalizer 160 equalizes the lines carrying the detected and amplified signal pair CSA and /CSA.

Due to the above-described equalization of the detected and amplified signal pair CSA and /CSA, the time when the next data signal pair DIN and /DIN is developed comes considerably earlier (by about tAn of FIG. 6). Accordingly, the generation of invalid data can be prevented during a high-speed operation in which data is repeatedly provided on the data signal pair DIN and /DIN.

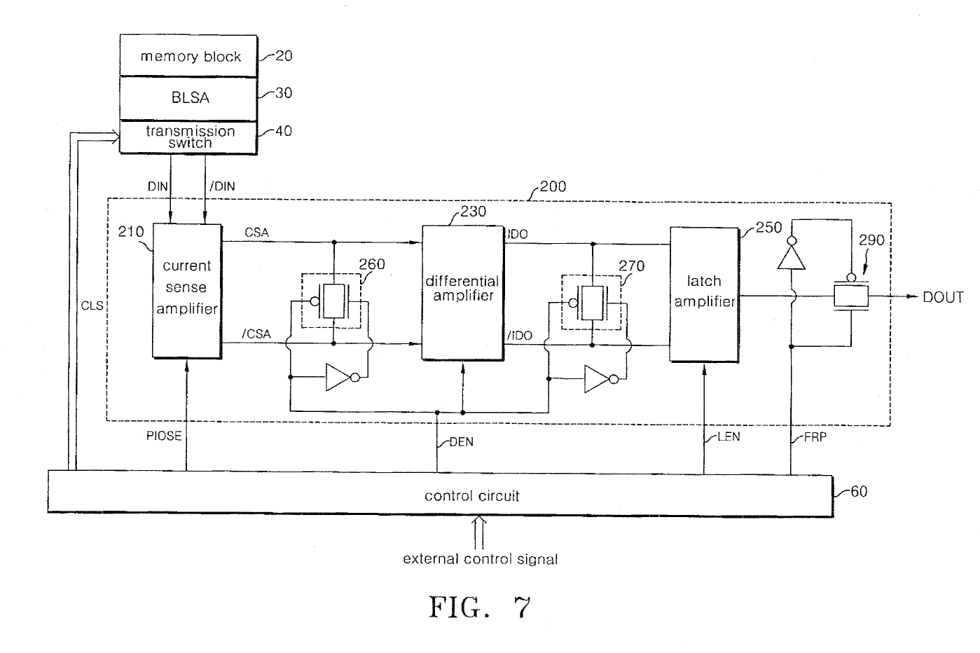

FIG. 7 is a block diagram schematically illustrating a semiconductor memory device including a signal amplification circuit 200 according to another embodiment. In the embodiment of FIG. 7, the signal amplification circuit 200 includes a current sense amplifier 210, a differential amplifier 230, a latch amplifier 250, a first equalizer 260, a second equalizer 270 and an output switch 290. The construction and operation of the current sense amplifier 210, latch amplifier 250, first equalizer 260 and output switch 290 of FIG. 7 are almost the same as those of the current sense amplifier 110, latch amplifier 150, equalizer 160 and output switch 190 of FIG. 3. The operation of the memory block 20, bit line sense amplifier 30, transmission switch 40 and control circuit 60 of FIG. 7 is the same as or similar to that of the elements of FIG. 3. Accordingly, the embodiment of FIG. 7 is described, with emphasis on the differential amplifier 230 and the second equalizer 270, which have no corresponding elements in the embodiment of FIG. 3.

The differential amplifier 230 is enabled in an interval where the control enable signal DEN is “H.” The differential amplifier 230 produces an internal voltage signal pair IDO and /IDO by amplifying the voltage difference of the detected and amplified signal pair CSA and /CSA, which is provided from the current sense amplifier 210, by predetermined amplification gain.

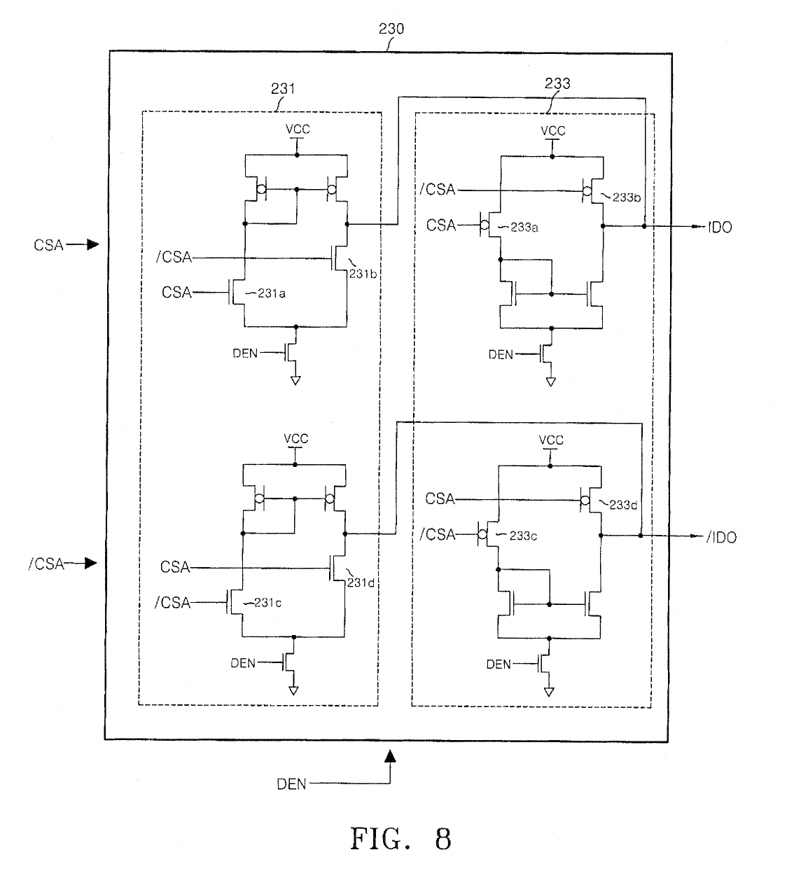

FIG. 8 is a circuit diagram illustrating the differential amplifier 230 of FIG. 7 in detail. Referring to FIG. 8, the differential amplifier 230 includes a first amplification unit 231 and a second amplification unit 233. The first amplification unit 231 and the second amplification unit 233 receive the detected and amplified signal pair CSA and /CSA from the current sense amplifier 210 and the internal voltage pair IDO and /IDO.

The first amplification unit 231 is an NMOS-type differential amplification unit that receives the detected and amplified signal pair CSA and /CSA through NMOS transistors 231a to 231d. The first amplification unit 231 effectively operates in a range in which the level of the common mode voltage of the detected and amplified signal pair CSA and /CSA is high.

The second amplification unit 233 is a PMOS-type differential amplification unit that receives the detected and amplified signal pair CSA and /CSA through PMOS transistors 233a to 233d. The second amplification unit 233 effectively operates in a range in which the level of the common mode voltage of the detected and amplified signal pair CSA and /CSA is low.

As shown in FIG. 8, in the differential amplifier 230, in which the NMOS-type differential amplification unit and the PMOS-type amplification unit are included, the influence of the level of the common mode voltage of the detected and amplified signal pair CSA and /CSA is minimized and the operational speed thereof is improved.

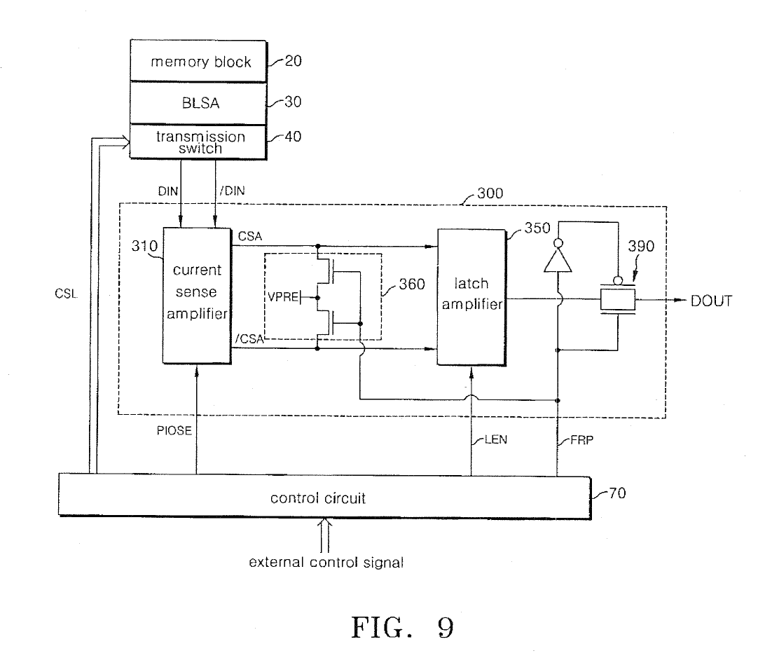

FIG. 9 is a block diagram schematically illustrating a semiconductor memory device including a signal amplification circuit 300 according to another embodiment. The embodiment of FIG. 9 is almost the same as that of FIG. 3. However, the embodiment of FIG. 9 is different from that of FIG. 3 in that a precharge unit 360 is included instead of the equalizer 160.

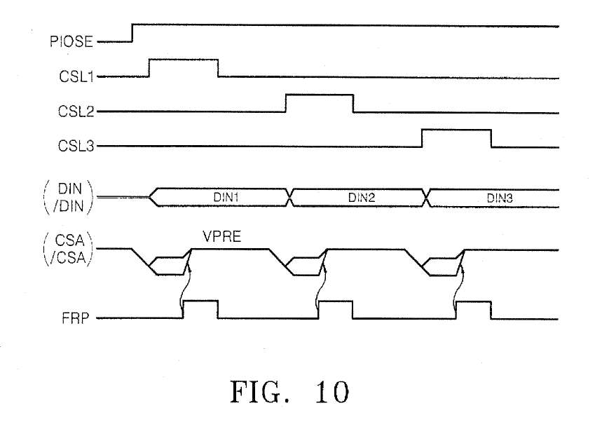

That is, the precharge unit 360 of FIG. 9 functions not only equalize the lines carrying the detected and amplified signal pair CSA and /CSA but also to precharge the lines to a precharge voltage VPRE. The construction and operation of the precharge unit 360 are different from those of the equalizer 160 of FIG. 3 that functions only to equalize the lines carrying the detected and amplified signal pair CSA and /CSA. At this time, the precharge unit 360, as shown in FIG. 10, is enabled in response to the output control signal FRP. That is, the precharge unit 360 is enabled while the output switch 290 remains turned on, and precharges the detected and amplified signal pair CSA and /CSA to the precharge voltage VPRE. As described above, the precharge unit 360 is constructed to respond to the output control signal FRP, so that the detected and amplified signal pair CSA and /CSA can be effectively precharged. That is, the detected and amplified signal pair CSA and /CSA is controlled such that it is precharged after previous data is latched by the latch amplifier 350.

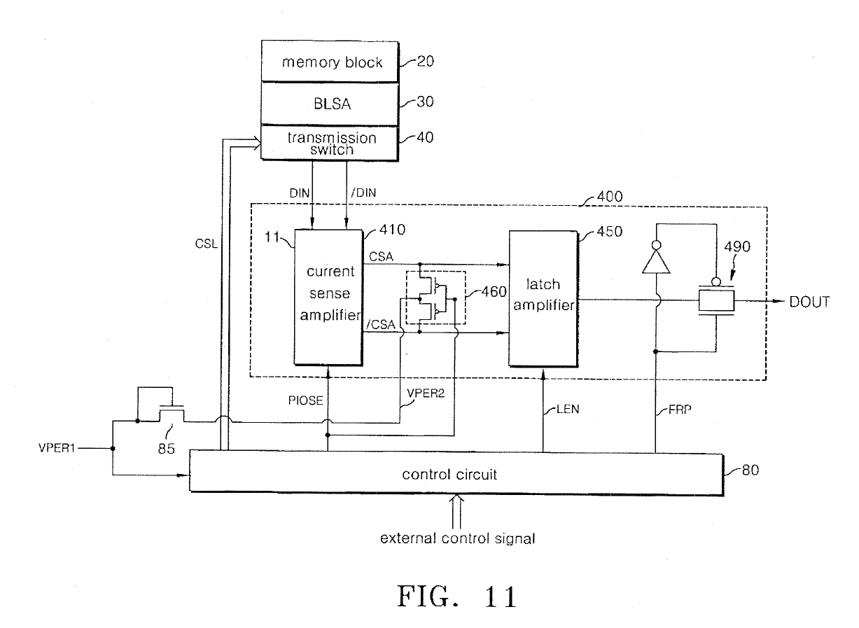

FIG. 11 is a block diagram schematically illustrating a semiconductor memory device including a signal amplification circuit 400 according to still another embodiment. The embodiment of FIG. 11 is almost the same as that of FIG. 9. However, the embodiment of FIG. 11 is different from that of FIG. 9 in that the voltage to which the detected and amplified signal pair CSA and /CSA is precharged is a second peripheral voltage VPER2.

Preferably, the second peripheral voltage VPER2 is a voltage that is dropped from a first peripheral voltage VPER1, which is provided to the peripheral circuit of the semiconductor memory device as power voltage, by the threshold voltage of a MOS transistor 85. For reference, the first peripheral voltage VPER1 is a voltage that is provided to circuits, which are located in the periphery of the semiconductor memory device, except for a memory block 20 and a bit line sense amplifier 40 as a power voltage.

Furthermore, the embodiment of FIG. 11 is different from that of FIG. 9 in that a precharge unit 460 for precharging the detected and amplified signal pair CSA and /CSAn operates in response to a current sense enable signal PIOSE. As described above, the current sense enable signal PIOSE is a signal that enables a current sense amplifier 410.

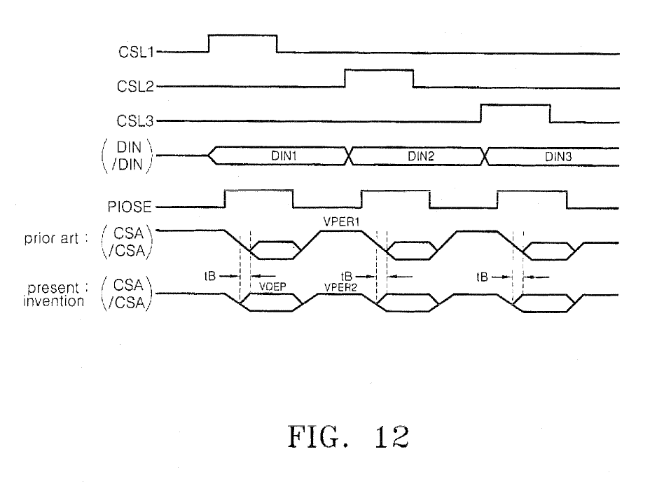

As described above, the detected and amplified signal pair CSA and /CSA is precharged to a second peripheral voltage VPER2 that is dropped from the first peripheral voltage VPER1 by the threshold voltage of the MOS transistor 85. Accordingly, as shown in FIG. 12, the detected and amplified signal pair CSA and /CSA is precharged to a voltage almost equal to a development voltage VDEP. For reference, the development voltage VDEP refers to a voltage that is pulled Lip when the detected and amplified signal pair CSA and /CSA is developed.

By the embodiment of FIG. 11, the detected and amplified signal pair CSA and /CSA is precharged to a voltage almost equal to the development voltage VDEP, so that the unnecessary consumption of current is prevented and operational speed is improved.

The above-described signal amplification circuit and the semiconductor memory device including the above-described signal amplification circuit may have equalizers that equalize the lines carrying the detected and amplified signal pair, that is, the output signals of the current sense amplifier. In accordance with the signal amplification circuit and the semiconductor memory device including the signal amplification circuit, in the case where the same data is repeatedly provided during high-speed operation, sensing can be successfully performed.

Furthermore, the semiconductor memory device including the signal amplification circuit according to another embodiment may have precharge units that precharge the detected and amplified signal pair. The precharge units are constructed to respond to the output control signal that enables the latch amplifier. Accordingly, the detected and amplified signal pair can be effectively precharged.

Moreover, in the semiconductor memory device including the signal amplification circuit according to another embodiment, the detected and amplified signal pair is precharged to a voltage almost equal to the development voltage. As a result, the unnecessary consumption of current can be prevented and operational speed can be improved.

Although embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A signal amplification circuit for a semiconductor memory device comprising:
a current sense amplifier configured to receive a first signal pair and generate a second signal pair on a first pair of lines;
an equalizer configured to equalize the first pair of lines; and
a latch amplifier configured to generate a latch data output on a second pair of lines in response to the second signal pair.

2. The signal amplification circuit of claim 1, wherein the equalizer is further configured to equalize the first pair of lines before another signal pair is received by the current sense amplifier.

3. The signal amplification circuit of claim 1, further comprising:
a transmission gate configured to equalize the second pair of lines.

4. The signal amplification circuit of claim 1, further comprising:
a differential amplifier configured to generate a third signal pair on a third pair of lines in response to the second signal pair.

5. The signal amplification circuit of claim 4, further comprising:
a second equalizer configured to equalize the third pair of lines.

6. The signal amplification circuit of claim 5, further comprising:
the latch amplifier configured to generate the latch data output in response to the third signal pair; and
a transmission gate configured to equalize the second pair of lines.

7. The signal amplification circuit of claim 1, wherein the equalizer is further configured to precharge the first pair of lines.

8. The signal amplification circuit of claim 7, wherein the equalizer is further configured to precharge the first pair of lines to a peripheral voltage.

9. A signal amplification circuit for a semiconductor memory device comprising:
a differential amplifier configured to receive a first signal pair on a first pair of lines and to generate a second signal pair on a second pair of lines;
an equalizer configured to equalize the second pair of lines; and
a latch amplifier configured to generate a latch data output on a third pair of lines in response to the second signal pair.

10. The signal amplification circuit of claim 9, wherein the equalizer is further configured to equalize the second pair of lines before another signal pair is received by the differential amplifier.

11. The signal amplification circuit of claim 9, further comprising:
a transmission gate configured to equalize the third pair of lines.

12. The signal amplification circuit of claim 9, further comprising:
an equalizer configured to equalize the first pair of lines.

13. The signal amplification circuit of claim 12, further comprising:
a current sense amplifier configured to generate the first signal pair in response to a fourth signal pair.

14. The signal amplification circuit of claim 9, wherein the equalizer is further configured to precharge the second pair of lines.

15. The signal amplification circuit of claim 14, wherein the equalizer is further configured to precharge the second pair of lines to a peripheral voltage.
